(19) United States
(12) Patent Application Publication
(10) Pub. No.: US 2025/0246442 A1
(43) Pub. Date: Jul. 31, 2025

(54) RF COAX THROUGH GLASS VIAS

(71) Applicant: BAE Systems Information and Electronic Systems Integration Inc., Nashua, NH (US)

(72) Inventors: Jeffrey M. Fitzgerald, Lunenburg, MA (US); Zachary Hileman, Manchester, NH (US); John A. Hughes, Falls Church, VA (US)

(73) Assignee: BAE Systems Information and Electronic Systems Integration Inc., Nashua, NH (US)

(21) Appl. No.: 18/427,958

(22) Filed: Jan. 31, 2024

(51) Int. Cl. H01L 21/48; H01L 23/66; H01P 3/06; H05K 1/02; H05K 3/00; H05K 3/42

(52) U.S. Cl. CPC H01L 21/486; H01L 23/66; H01P 3/06; H05K 1/0222; H05K 3/007; H05K 3/423; H01L 2223/6622; H05K 3/0029; H05K 2203/072; H05K 2203/0723

(57) ABSTRACT

A signal transmission or processing assembly having a coaxial through-via within a substrate is provided. The substrate may be formed from a material that is a glass-like with an amorphous non-crystalline structure that enables the assembly to create or be created by a deep trepan or annular member that surrounds the center conductor. Methods of manufacture are employed or exploited to preserve the glass-like or other dielectric material structure of substrate to form the inner material or annular member that surrounds the center conductor or pair of center conductors.

### TECHNICAL FIELD

The present disclosure relates generally to coaxial through-vias.

### BACKGROUND ART

Coaxial through-vias are specialized structures used in electronic and RF (radio frequency) applications to enable signal transmission and isolation within a substrate, which may be a mono-layer or multi-layered. There may be cylindrical or tapered open passageways that extend through the substrate. These are essentially holes or vias drilled (e.g., laser drilled) or etched (e.g., mechanically, laser and/or chemically etched) through a vitreous (glass-like) dielectric substrate. These passageways provide a path for electrical connections between the substrate.

The walls of these inner conductors and outer conductors, which respectively form the passageways that provide the path for electrical connections between the substrate, are coated with a conductive metallic layer. This conductive layer serves as the signal path, allowing electrical signals to travel through the vias. It provides a low-resistance conductive path between different layers of a circuit board or substrate. In addition to signal conduction, the metallic coating also helps isolate the signal within the via. By coating the walls with a conductive material, it prevents signal leakage or interference with adjacent traces or components on the substrate. Common materials used for the metallic coating include copper, gold, and silver. Copper is a widely used choice due to its excellent electrical conductivity and cost-effectiveness. The metallic coating is often applied using electroplating techniques. During this process, the substrate is immersed in an electrolyte solution, and an electric current is applied, causing the metallic ions in the solution to adhere to the via walls, forming a uniform coating. The metallic coating must adhere securely to the via walls to ensure long-term reliability and prevent peeling or delamination. The metallic coating is designed to minimize signal loss as the signal passes through the via. This is crucial in high-frequency RF applications, where even small signal losses can degrade performance.

After coating the walls with the metallic layer, a dielectric (insulating) layer is applied over the entire substrate surface. This dielectric layer isolates the metallic via walls from the surrounding circuitry and prevents unintended electrical interactions. The dielectric layer acts as an insulator that separates the conductive metallic through-via wall coating from the surrounding circuitry or adjacent vias. Without the dielectric layer, there would be a direct electrical connection between the metallic coating and neighboring conductive elements. This isolation is crucial to prevent short circuits and unintended electrical interactions. In the absence of a dielectric layer, the metallic via walls might exhibit significant capacitive coupling with nearby traces or components. This capacitive coupling can lead to signal interference and signal quality degradation. The dielectric layer contributes to the structural integrity of the through-via structure. It helps maintain the shape and stability of the via, especially in cases where the substrate material may be fragile. The dielectric constant of the material influences the propagation velocity of signals passing through the via, and it is carefully considered in RF and high-frequency applications to maintain signal integrity. In some applications, the dielectric layer may also provide thermal insulation between different layers of the substrate, helping to dissipate heat away from sensitive components or signal paths. Dielectric materials commonly used for this purpose include various types of epoxy resins, polyimides, and PTFE (Teflon).

Within the coated passageway, a conductive core is inserted. This core typically serves as a signal conductor, carrying electrical signals from one layer of the substrate to another. It provides a low-resistance, highly conductive path for electrical current to flow between different layers of the circuit board or substrate. The core helps maintain signal integrity by minimizing signal loss as it traverses the via. This is beneficial in high-frequency and RF applications, where even small losses can significantly affect performance. Common materials used for the center conductive core include copper, gold, and silver. Copper is often preferred due to its excellent electrical conductivity and cost-effectiveness. Like the metallic via wall coating, the center conductive core must adhere securely to the via walls to ensure long-term reliability and prevent detachment. The center conductive core must be compatible with the dielectric material used in the substrate. It should not react chemically with the dielectric or compromise its electrical properties. In RF and high-frequency applications, maintaining a consistent characteristic impedance along the signal path is essential for signal integrity. The center conductive core, along with the surrounding dielectric and metallic coatings, helps achieve the desired impedance values. The center conductive core contributes to the structural integrity of the through-via structure. It helps maintain the shape and stability of the via, especially in cases where the substrate material may be fragile.

The integrated ground shield liner conductor is an optional layer that is essentially a conductive liner or shield that surrounds the center conductive core inside the passageway. Together, the conductors form coaxial through-via. The primary purpose of this ground shield liner conductor is to provide electromagnetic shielding and reduce interference. This feature is what differs coaxial through-vias apart from standard vias and is advantageous in high-frequency and RF applications where electromagnetic interference (EMI) can degrade signal quality. It effectively forms a shield around the central conductive core, minimizing the interference of electromagnetic fields from external sources and reducing the radiation of electromagnetic energy from the conductor. The integrated ground shield liner conductor gives the through-via a coaxial configuration, similar to a coaxial cable. In a coaxial cable, the outer conductor serves as a shield to protect the inner conductor from external EMI. In the case of through-vias, this shielding function is integrated into the structure. The material used for the integrated ground shield liner conductor is typically a highly conductive metal like copper. Copper is favored due to its excellent electrical conductivity and cost-effectiveness.

It should be noted that a solid outer conductor and castellations of vias are two different design and manufacturing features used in mono-layer substrates to achieve distinct purposes. It is possible for a solid outer conductor to be a continuous conductive layer on a surface of a substrate. Its primary purpose is to provide electromagnetic shielding, grounding, or to serve as a reference plane for signal integrity. To create a solid outer conductor, a continuous conductive layer (usually copper) is deposited or laminated onto the outer surface of the substrate during the manufacturing process. This layer covers the entire surface of the substrate and forms a seamless conductor. Solid outer conductors are commonly used in high-frequency and high-speed applications where electromagnetic interference (EMI) control, shielding, and a low-inductance ground plane are beneficial. However, they are planar, meaning they provide effective shielding in the x and y planes of the substrate only.

In addition to mono-layer substrates, solid outer conductors can also be incorporated into multi-layer Printed Circuit Boards (PCBs). Each layer can have its solid outer conductor for signal integrity and EMI control. These layers are interconnected through vias to maintain the required electrical connections. Some advanced PCB designs utilize buried capacitance layers as a form of a solid outer conductor. These layers are created with embedded capacitor materials, providing decoupling capacitance, while also serving as a continuous solid outer conductor. In complex designs, hybrid structures may be employed. This involves a combination of solid outer conductors, ground planes, and castellated vias to achieve multiple functions such as shielding, grounding, and component attachment simultaneously.

Castellations of vias are used for creating a connection point at the edge of a PCB. They serve to transition signals or power from the PCB to external components, connectors, or other PCBs. Castellations are essentially vias that are partially exposed at the edge of the PCB. They may be created by forming the vias and then selectively removing the PCB substrate material, exposing the via barrels at the PCB's edge. Castellations of vias are used for edge connectors, surface-mounting to other PCBs, or soldering components directly to the PCB edge. They are commonly found in scenarios where components or connectors need to be securely attached to the PCB's edge. Castellations are also a way to control unwanted EMI at the edge of the PCB by forming a faraday cage or via shield but are not suitable for low loss vertical through-substrate single RF signal routing. A specified distance between the center and outer conductors should be maintained for a given dielectric material in RF signal routing.

In printed circuit board (PCB) fabrication stacked and staggered standard vias are used for vertical through substrate signal routing. Vias are made layer by layer. The via consists of large round capture pads to assure alignment and thus electrical connection of the next layered via. In an ideal PCB construction for through-substrate RF, a center stack of vias is surrounded by a pattern of equally spaced, stacked vias to form a ground shield however manufacturing limitations and Coefficient of Thermal Expansion (CTE) differences often prevent the ability to reliably stack a number of vias and the designer must use staggered vias instead. Since RF signals travel on the surfaces of the conductors (only skin deep in the conductor) these vias and capture pads disrupt the propagation due to radiation and reflection effects. The layer by layer construction method prevents a solid continuous vertical wall of conductive material from effectively surrounding a center stack of vias.

While coaxial through-vias offer numerous benefits in terms of signal integrity and electromagnetic interference (EMI) control, there are some potential drawbacks and manufacturing difficulties associated with their production. For example, manufacturing coaxial through-vias is more intricate and complex compared to standard vias as coaxial through-vias require additional fabrication steps and mask layers if using a contact aligner or stepper. The additional layers, materials, and precise dimensions required can increase production time and cost. Achieving precise alignment of the various components within the via structure can be challenging. Misalignment can result in signal integrity issues and degrade the shielding effectiveness of the ground shield liner conductor. Coaxial through-vias require rigorous quality control to ensure that each via meets the specified electrical and mechanical requirements. Detecting defects, such as delamination, voids, or adhesion issues, can be challenging due to the complex internal structure.

### SUMMARY OF THE INVENTION

In one aspect, an exemplary embodiment of the present disclosure may provide a signal transmission or processing assembly having a coaxial through-via within a substrate. The substrate may be formed from a material that is glass-like with an amorphous non-crystalline structure that enables the assembly to create or be created by a deep trepan or annular member that surrounds the center conductor. In one embodiment, the glass, glass-like or fused-silica based substrate enables manufacturing techniques presented herein to enhance signal integrity especially in the vertical direction through the substrate. Exemplary embodiments of the present disclosure overcome the traditional stacked and staggered vias of PCB manufacturing by offering a continuous ground shield and geometries with the least number of discontinuities. Examples of the glass coaxial vias can eliminate discontinuities within the substrate and allows for a straight through design.

Methods of manufacture detailed in the various examples herein help preserve the glass-like structure of substrate while forming the inner center conductor or annular member. This contrasts with previous attempts which have created an inner material or annular member from different dielectric materials than the surrounding substrate. In some examples, the assembly ensures that all of the dielectric material remains the same by preserving the annular member or inner material the same material as the remainder of the substrate that is exterior to via. By keeping the annular member or inner material the same as the rest of the substrate that is exterior to the outer conductor, the assembly of the present disclosure is able to eliminate or significantly reduce additional issues relating to materials having different coefficients of thermal expansion (CTE) inasmuch as the materials are the same. Further, this arrangement of the annular member eliminates or otherwise reduces the need to develop additional adhesion mechanisms to accommodate different materials. Aspect of the present disclosure may make these coax through vias hermetic if needed. By reducing or eliminating issues relating to CTE mismatch, the assembly is able to more accurately and reliably predict operation of the coaxial via structure because ordinary issues such as warpage or variation of CTE between different material properties or other unpredictable behavior of the substrate will be reduced by maintaining a common material property.

In another aspect, the assembly may provide a through glass via RF coax. By using the substrate, a wafer/panel is interconnected through a ceramic/composite to a next level assembly. Orientation and confinement may be dictated by traditional high speed (femtosecond) laser ablation and/or chemical etching processes, including hydrofluoric acid and potassium hydroxide. Using said etching techniques, an ultra-fast through-via can be inscribed with single digit micron position accuracy (e.g., <363 μm/hour with positional accuracy <100 nm). Additionally, laser inscribing from opposite sides of a thick substrate are possible to increase the control/speed of fabrication resulting in an hourglass shape. Multi-axis through-vias in a single substrate are also possible. In addition to the orthogonal coax through via exemplary embodiments of the present disclosure may provide a tapered and/or offset coax via(s) by gimbaling the laser beam. This provides a unique vertical fanout capability traditionally accomplished by horizontal routing. If the substrate is sufficiently thick, an array of input/output (I/O) can be made larger at the opposite side of the substrate by angling each via.

In another aspect, an exemplary embodiment of the present disclosure may provide a signal transmission assembly product having a coaxial through-via configuration, wherein the coaxial through-via via entirely through a substrate from a first surface to a second surface, wherein the coaxial through-via via comprises an annular outer conductor, a cylindrical inner conductor that is centered along a center axis, and an annular inner member located between the outer conductor and the cylindrical inner conductor, wherein the annular inner member is formed form the same dielectric material as the substrate, the coaxial through-via configuration formed by a process comprising: starting at the first surface, creating a cylindrical void that extends from the first surface toward the second surface; starting at the first surface, creating a central bore that extends from the first surface toward the second surface; maintaining the annular inner member in a fixed position between the cylindrical void and the central bore, wherein the annular inner member is formed from the same material as the substrate; disposing a conductive material within the cylindrical void to create the annular outer conductor; disposing a conductive material within the central bore to create the cylindrical inner conductor; and forming a coaxial through-via that extends through the substrate.

In another aspect, an exemplary embodiment of the present disclosure may provide a method or a signal transmission assembly product having a coaxial through-via formed by a process comprising: providing a substrate having a first surface and a second surface; starting at the first surface, creating a cylindrical void that extends from the first surface toward the second surface; starting at the first surface, creating a central bore that extends from the first surface toward the second surface; maintaining an annular member in a fixed position between the cylindrical void and the central bore, wherein the annular member is formed from the same material as the substrate; disposing a conductive material within the cylindrical void; disposing a conductive material within the central bore; and forming a coaxial through-via that extends through the substrate. This exemplary embodiment or another exemplary embodiment may further include, prior to creating the cylindrical void, applying a backing layer to the second surface of the substrate. This exemplary embodiment or another exemplary embodiment may further include, after disposing the conductive material within the cylindrical void and disposing the conductive material within the central bore, removing the backing layer to expose the second surface. This exemplary embodiment or another exemplary embodiment may further provide that maintaining the annular member in the fixed position between the cylindrical void and the central bore is accomplished by the backing layer being removably connected to both the substrate and the annular member. This exemplary embodiment or another exemplary embodiment may further include, starting at the first surface, creating the cylindrical void that extends entirely through the substrate from the first surface to the second surface. This exemplary embodiment or another exemplary embodiment may further include, starting at the first surface, creating the central bore that extends entirely through the substrate from the first surface to the second surface. This exemplary embodiment or another exemplary embodiment may further include, starting at the first surface, creating a first portion of the cylindrical void that extends partially to a depth in the substrate from the first surface that is less than an entire thickness of the substrate, wherein a remainder portion of the substrate remains subsequent to creating the first portion of the cylindrical void and the remainder portion of the substrate maintains the annular member in a fixed position between the cylindrical void and the central bore. This exemplary embodiment or another exemplary embodiment may further include depositing the conductive material in the first portion of the cylindrical void; starting from the second surface, creating a second portion of the cylindrical void that extends from the second surface through the remainder portion to meet with the conductive material in the first portion of the cylindrical void. This exemplary embodiment or another exemplary embodiment may further include, starting at the first surface, creating a first portion of the central bore that extends partially to a depth in the substrate from the first surface that is less than an entire thickness of the substrate, wherein a remainder portion of the substrate remains subsequent to creating the first portion of the central bore and the remainder portion of the substrate maintains the annular member in a fixed position between the cylindrical void and the central bore. This exemplary embodiment or another exemplary embodiment may further include depositing the conductive material in the first portion of the central bore; and starting from the second surface, creating a second portion of the central bore that extends from the second surface through the remainder portion to meet with the conductive material in the first portion of the central bore.

In yet another aspect, another exemplary embodiment of the present disclosure may provide a signal transmission assembly comprising: a substrate having a first surface and a second surface, wherein the substrate is formed from a dielectric material; a via extending entirely through the substrate from the first surface to the second surface, wherein the via comprises: an annular outer conductor; a cylindrical inner conductor that is centered along a center axis; and an annular member located between the outer conductor and the inner conductor, wherein the annular member is formed form the same dielectric material as the substrate.

### BRIEF DESCRIPTION OF THE DRAWINGS

Sample embodiments of the present disclosure are set forth in the following description, are shown in the drawings and are particularly and distinctly pointed out and set forth in the appended claims.

FIG. 1 is a top perspective view of a signal transmission assembly having a coaxial through-via formed in a substrate.

FIG. 2 is a top perspective view of the signal transmission assembly having the coaxial through-via formed in the substrate, shown with the transmission lines from FIG. 1 having been removed.

FIG. 3 is an isometric cross-section view of the signal transmission assembly having the coaxial through-via formed in the substrate.

FIG. 4A is an operational elevation cross-section view of one step in the method of manufacture of the signal transmission assembly depicting the creation of a cylindrical void and central bore.

FIG. 4B is an operational elevation cross-section view of one step in the method of manufacture of the signal transmission assembly depicting the application of one or more seedling layers.

FIG. 4C is an operational elevation cross-section view of one step in the method of manufacture of the signal transmission assembly depicting the deposition of conductors.

FIG. 4D is an operational elevation cross-section view of one step in the method of manufacture of the signal transmission assembly depicting the removal of the backing layer.

FIG. 5A is an operational elevation cross-section view of one step in another method of manufacture of the signal transmission assembly depicting the creation of a partial cylindrical void and a partial central bore.

FIG. 5B is an operational elevation cross-section view of one step in the method of manufacture of the signal transmission assembly depicting the application of one or more seedling layers.

FIG. 5C is an operational elevation cross-section view of one step in the method of manufacture of the signal transmission assembly depicting the deposition of conductors.

FIG. 5D is an operational elevation cross-section view of one step in the method of manufacture of the signal transmission assembly depicting the creation of a second partial cylindrical void and a second partial central bore.

FIG. 5E is an operational elevation cross-section view of one step in the method of manufacture of the signal transmission assembly depicting the application of one or more seedling layers.

FIG. 5F is an operational elevation cross-section view of one step in the method of manufacture of the signal transmission assembly depicting the deposition of conductors in the second partial cylindrical void and the second partial central bore.

FIG. 5G is an operational elevation cross-section view of one step in the method of manufacture of the signal transmission assembly depicting the removal of the second surface to reveal a polished second surface.

FIG. 6A is an operational elevation cross-section view of one step in another method of manufacture of the signal transmission assembly depicting the creation of a partial cylindrical void and a central bore that extends fully through the substrate.

FIG. 6B is an operational elevation cross-section view of one step in the method of manufacture of the signal transmission assembly depicting the application of one or more seedling layers.

FIG. 6C is an operational elevation cross-section view of one step in the method of manufacture of the signal transmission assembly depicting the deposition of conductors.

FIG. 6D is an operational elevation cross-section view of one step in the method of manufacture of the signal transmission assembly depicting the removal of the second surface to reveal a polished second surface.

Similar numbers refer to similar parts throughout the drawings.

### DETAILED DESCRIPTION

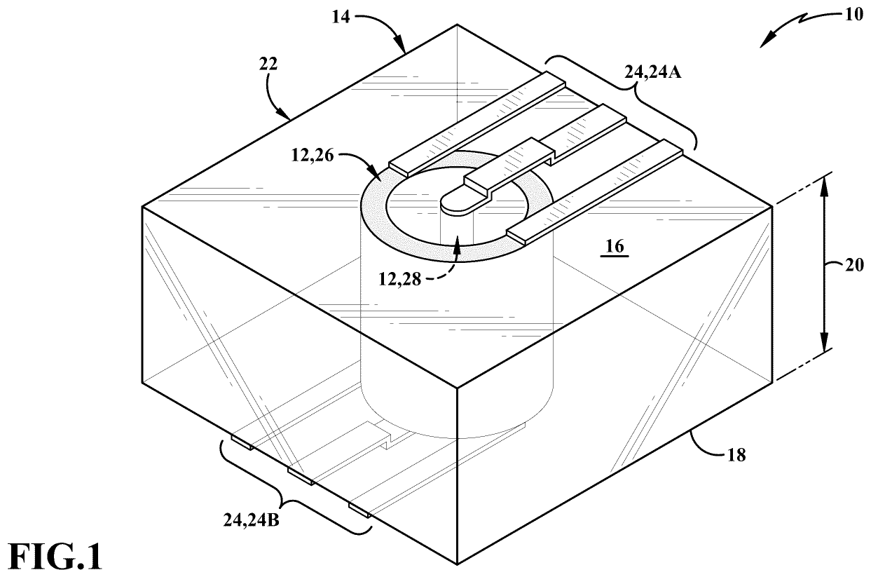

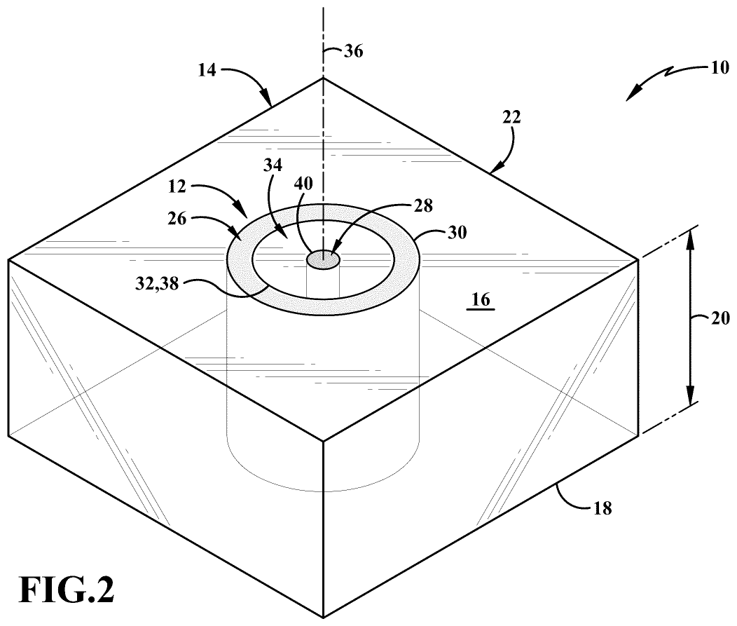

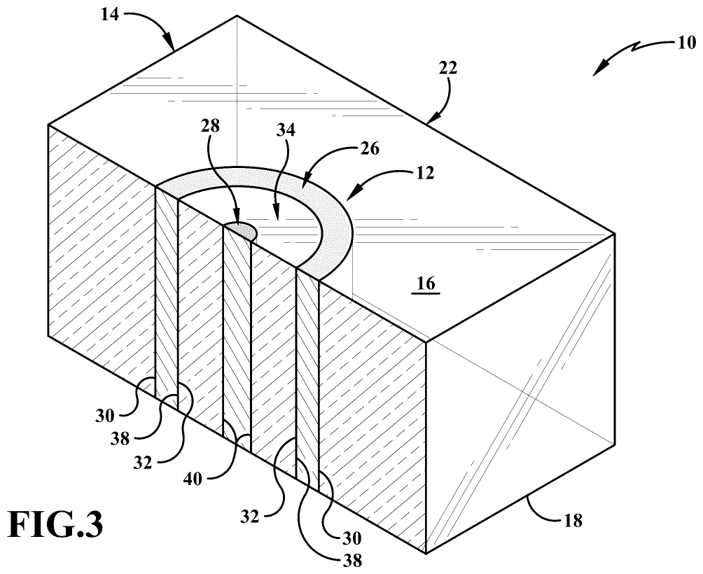

FIG. 1-FIG. 3 depict a signal transmission or processing assembly 10 having a coaxial through-via 12 within a substrate 14. In one example, substrate 14 may be a vitreous (glass-like) dielectric substrate. Substrate 14 includes a first surface 16 spaced apart from a second surface 18 defining a thickness 20 therebetween. The thickness 20 of the substrate 14 may be any commercially viable thickness that a substrate for a signal transmission or processing assembly 10 may ordinarily have. Substrate 14 is bound by a perimeter edge 22 that may have any size or shape depending on the application specific need of assembly 10. Thus, while the assembly 10 is shown generally as a rectangular configuration, it is to be understood that the perimeter edge 22 of substrate 14 may take on the form of any shape.

The via 12 is connected with one or more transmission lines 24. In one particular embodiment, a first set of transmission lines 24A are disposed on the first surface 16 of substrate 14 and a second set of transmission lines 24B are disposed on the second surface 18 of substrate 14. While the transmission lines or the set of transmission lines 24A, 24B are disposed on the surface 16, 18, respectively, it is to be understood that the transmission lines 24 could be embedded within the substrate 14 if desired to meet an application specific need of assembly 10. Each set of transmission lines 24 may include two transmission lines 24 that connect with the outer conductor 26 of the coaxial through-via 12 and one transmission line 24 that connects with the center conductor 28 of the coaxial through-via 12. Transmission lines 24 may take on any form or shape that effectuate the transmission of electrical signals through the coaxial through-via 12 from one side of the substrate to the other, namely, from one surface, such as the second surface 18, to another surface, such as the first surface 16, or vice versa.

Substrate 14 and inner member 34 may both be formed from a dielectric material. Substrate 14 could be formed from alumina (Al₂O₃), glass-ceramics, fused quartz, other silicas and/or certain composite materials. The teachings of the present disclosure relate to the usage and formation of assembly 10 with substrate 14 being made from these materials.

However, it may be possible for other materials that to be utilized for substrate 14 and inner member 34. For example, aluminum nitride (AlN) is a ceramic material with a high thermal conductivity, making it suitable for applications where heat dissipation is important. It has a relatively high dielectric constant and is often used in high-power electronic devices and microwave circuits. Beryllium Oxide (BeO) is known for its excellent thermal conductivity and high dielectric strength. However, it is less commonly used today due to health concerns associated with beryllium dust and its toxicity. Glass-Epoxy Composite (FR-4) is a widely used substrate material for standard PCBs. It consists of layers of woven fiberglass cloth impregnated with an epoxy resin. While not as high-performing in terms of RF and microwave applications compared to ceramics, it is cost-effective and suitable for many electronic devices. Polytetrafluoroethylene (PTFE) or PTFE-based substrates, such as Rogers' materials (e.g., RO4000 series), are known for their low dielectric constant and low loss tangent at high frequencies. They are commonly used in high-frequency PCBs and microwave circuits. Liquid Crystal Polymer (LCP) substrates have gained popularity in recent years for their excellent electrical properties, including a low dielectric constant and low moisture absorption. They are suitable for high-frequency and miniaturized electronic devices. Ceramic-Polymer composites achieve a balance between electrical performance and mechanical flexibility. These composites can offer good dielectric properties while being less brittle than pure ceramics. Additionally, while sapphire is more commonly known for its use in optical applications, it can also serve as a dielectric substrate in certain electronic devices, especially those requiring high-temperature stability and high-quality insulating properties. Silicon Dioxide (SiO₂), also known as quartz, can be used as a dielectric substrate, especially in MEMS (Micro-Electro-Mechanical Systems) and RF applications. Its properties can be tailored through deposition techniques to achieve desired electrical characteristics. Barium Strontium Titanate (BST) is a ferroelectric material that can be used as a tunable dielectric substrate in RF and microwave devices. Its dielectric constant can be adjusted by applying an electric field, allowing for variable capacitance in tunable components.

These materials that are described above that could be used for substrate 14 and inner member 34 have distinct dielectric properties and are selected based on the application specific needs of assembly 10. When substrate 14 and inner member 34 is formed from a vitreous dielectric substrate, it is beneficial for having high electric resistivity. Substrate 14 should not conduct electricity and should withstand high voltage levels, making substrate 14 and inner member 34 suitable for separating conductive components on assembly 10 from other electronic assemblies. Vitreous dielectric substrates often have a low and stable dielectric constant (also known as relative permittivity). This property is beneficial in maintaining the electrical performance of high-frequency and microwave circuits, as it affects signal propagation and impedance matching. Low loss tangent is another useful property of vitreous dielectric substrates, especially in high-frequency applications. A low loss tangent means that the substrate minimally absorbs and dissipates electrical energy as heat, ensuring minimal signal loss. Substrate 14 and inner member 34 is typically rigid and mechanically stable, which is important for maintaining the structural integrity of electronic components. Vitreous dielectric substrates often exhibit good thermal stability, allowing them to withstand a wide range of operating temperatures without significant degradation in their electrical properties. Substrate 14 can be manufactured into various shapes and sizes to suit different electronic applications. Vitreous dielectric substrates are compatible with standard fabrication processes such as screen printing, etching, and soldering. Additionally, vitreous dielectric substrates find extensive use in RF (radio frequency) and microwave applications due to their low loss, high dielectric constant stability, and good high-frequency performance.

Conductive through-via 12 includes the outer conductor 26 and the inner conductor 28. Outer conductor 26 is a generally cylindrical shape which may have a uniform diameter throughout the thickness 20 of substrate 14 or may have an hourglass shape, or a tapering shape. In either scenario, the outer conductor 26 includes an outer diameter 30 and an inner diameter 32. The outer conductor 26 has a radially aligned thickness between the outer diameter 30 and the inner diameter 32. Within the inner diameter 32 of the outer conductor is an interior dielectric material or inner material 34 that is annular in shape (i.e., donut or ring shaped). In one embodiment, the inner material 34 is the same material forming the substrate 14 that is exterior to the outer diameter 30 of the outer conductor 26. The inner material is centered about a center axis 36 and concentric with the outer conductor 26. Outer conductor 26 circumscribes the inner material 34 such that an outer diameter 38 of the inner material 34 interfaces with the surface defining the inner diameter 32 of the outer conductor 26. Inner material 34 includes an inner diameter 40. A radial thickness of the inner material 34 is defined between the outer diameter 38 and the inner diameter 40. Each radial thickness is measured relative to axis 36. The inner diameter 40 forms a central bore, which may have a circular profile or cross-section. The center conductor 28 is disposed within the inner diameter 40 of the inner material 34. The center conductor 28 interfaces with the surface defining the inner diameter 40 of inner material 34. Center conductor 28 extends fully through the substrate 14 from the first surface 16 to the second surface 18 when the via 12 of assembly 10 is fully constructed.

Having thus described the physical configuration of the assembly of the present disclosure, reference is now made to its method of manufacture. Some methods of manufacture utilize a laser etching process to create the openings in the substrate. Laser etching, or laser ablation, is a precise and controlled process used to cut openings in vitreous (glass-like) dielectric substrates to create cylindrical or tapered vias 12 for electronic applications. The vitreous dielectric substrate 14 material is chosen based on the specific application requirements. It should be able to be laser etched and have the desired electrical and thermal properties. The dielectric substrate is typically a multi-layered material with conductive layers and dielectric layers. Prior to laser etching, the substrate may undergo surface preparation, which can include cleaning and ensuring a smooth, uniform surface. A laser system is set up with the appropriate laser source and optics. The choice of laser type (e.g., CO2, Nd:YAG, or fiber laser) depends on the substrate material and the desired precision of the etching. Laser parameters, such as power, pulse duration, and repetition rate, are configured based on the substrate material and the desired etching depth and precision. These parameters determine the energy delivered by the laser. A mask or a photomask may be applied to the substrate to define the pattern of the via openings. It should be noted that he photomask process and the laser process are distinctly different. The laser is a direct write maskless process. The laser process may be coupled with a chemical wet etch or not. The photomask uses wet chemicals for etching or plasma for dry etching. One particular example of the present disclosure utilizes a laser coupled with wet etching. Wet etching with a photomask alone has some inherent limitations to the profile formed and the undercut produced. Deep reactive ion etching (DRIE) may be a another alternative to laser and wet etch because of the high aspect ratio features afforded by DRIE but it may take longer to produce compared to laser and wet etching.

The laser system is adjusted to focus the laser beam precisely on the substrate surface, aligned with the desired locations for the vias 12. The laser system emits a high-intensity laser beam focused on the substrate surface. The energy from the laser beam is absorbed by the substrate material, causing localized heating and vaporization. This process is known as ablation. The laser removes material in a controlled manner, creating the cylindrical or tapered openings according to the mask pattern. The depth and shape of the vias are determined by the laser parameters and the rate of material removal. Some laser etching systems incorporate real-time monitoring and feedback mechanisms to ensure precise control of the etching process. This may involve sensors or cameras that monitor the etching depth and adjust the laser parameters accordingly. After the laser etching process, the substrate may be cleaned to remove any debris or residue. Inspection and quality control checks may be performed to verify that the via openings meet the required specifications in terms of dimensions and surface quality.

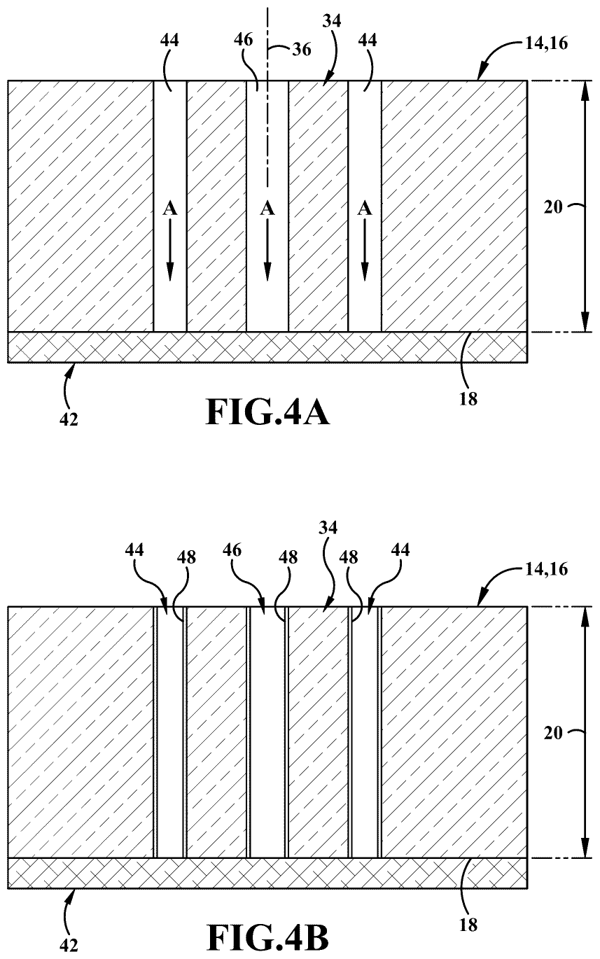

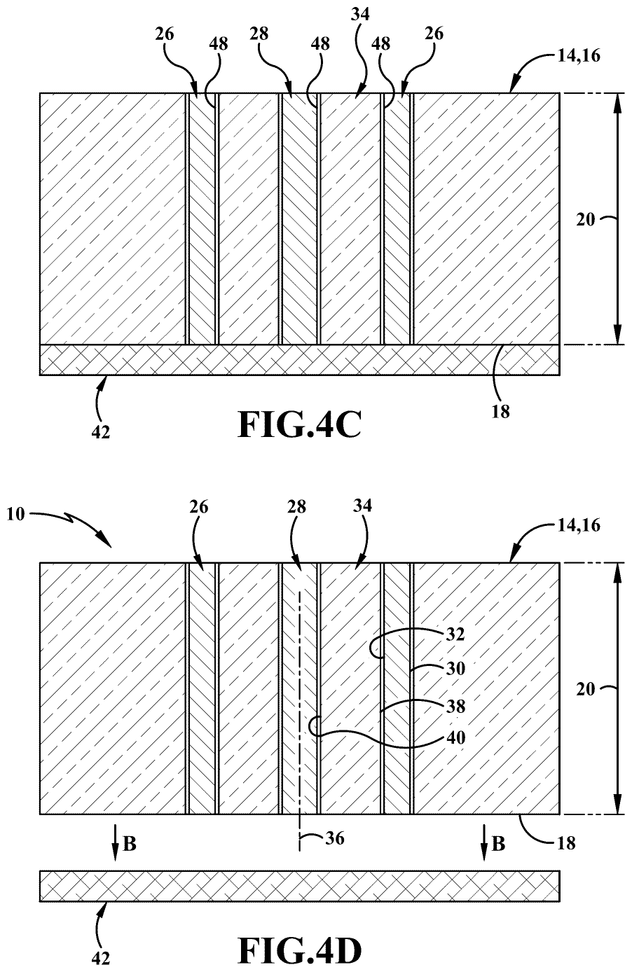

FIG. 4A-FIG. 4D depict one exemplary method of manufacture of assembly 10. FIG. 4A depicts that the substrate 14 may have a backing layer or simply backing 42 applied to the second surface 18. The backing 42 may be any suitable material or composition of materials that can be removably applied to the second surface 18 of substrate 14. When the backing 42 has been applied to the second surface 18 of substrate 14, the substrate 14 may be altered to create a void extending fully through the thickness 20 of the substrate 14 to reveal the cylindrical shape of the outer conductor and the a central bore of the center conductor. Namely, a cylindrical void 44 is created and a central bore 46 is created. The central bore 46 extend coaxially along the center axis 36 and the cylindrical void 42 is concentric with the axis 36. In one particular embodiment, the cylindrical void 44 and the central bore 46 may be defined or created by the laser etching process described above. Notably, the laser etching process may start or begin at the first surface 16 and extend all the way through the thickness 20 of the substrate 14 as indicated by arrows A. Because the back 42 is adhered or otherwise removably connected to the second surface 18, when the cylindrical void 44 and the central bore 46 are fully formed through the substrate 14, the inner material 34 is retained in place through its removable connection with backing 42.

FIG. 4B depicts that after the cylindrical void 44 and the central bore 46 have been formed though the thickness 20 of the substrate 14, a seedling layer 48 may be applied or coated to the surfaces that define the cylindrical void 44 and the central bore 46. More particularly, the seedling layer 48 is applied to the surface that defines the outer diameter 30 of what will be the outer conductor 26 and the outer diameter 38 or the inner material 34. Similarly, the seedling layer 48 may be applied to the surface that defines the inner diameter 40 of the inner material 34 that will ultimately result is the outer diameter of the center conductor 28. The seedling layer 48 may be a uniform material or a sputtering of material that ultimately becomes the site or location where the plating occurs as was described herein.

Applying the seedling layer 48 to the vitreous dielectric substrate 14 before depositing a metal conductor promotes adhesion and helps initiate the electroplating process. This process involves several steps. First, for substrate preparation, ensure that the substrate surface is free from contaminants, oxidation, and other impurities that could hinder adhesion. The substrate surface may be cleaned and treated to enhance adhesion. This could involve processes like ultrasonic cleaning, plasma cleaning, or chemical treatments. The seedling layer is a very thin layer of a specific metal (typically a noble metal like palladium or platinum or others) that serves as a nucleation site for the subsequent metal conductor deposition. The seedling layer promotes adhesion and helps initiate the electroplating process.

The seedling layer is could be deposited using one of the following methods: Physical Vapor Deposition (PVD); Chemical Vapor Deposition (CVD); Sputtering; or Electroless Plating. However, there may be other seedling layer 48 deposition techniques. PVD is a deposition technique based on the physical processes of vaporization and condensation. It involves the conversion of a solid material into vapor form in a vacuum environment, followed by its condensation onto the substrate 14. CVD is a process in which a thin film is deposited on the substrate 14 through chemical reactions of precursor gases. These gases react on the substrate's surface, resulting in the deposition of the desired material. Sputtering is a physical deposition process in which atoms or ions from a solid target are dislodged and deposited onto the substrate 14 due to the impact of energetic particles, typically ions or electrons. Electroless plating, also known as chemical deposition, is an autocatalytic process where a thin metal layer is deposited on the substrate 14 without the need for an external electric current. It relies on chemical reactions.

Regardless of which technique is utilized, the seedling layer 48 is designed to have excellent adhesion to the vitreous substrate. However, in some cases, an adhesion-promoting layer or adhesion promoter chemicals may be used to further enhance bonding between the seedling layer and the substrate. Depending on the application, a mask or photolithography process may be used to define the pattern for the seedling layer. This defines where the seedling layer will be deposited on the substrate. Once the seedling layer 48 is in place, the next step is to deposit the desired metal conductor.

FIG. 4C depicts the manufacture of one embodiment of assembly 10 in which conductive material, such as metal, is deposited into the cylindrical void 44 (as shown in FIG. 4B) and the central bore 46 to create the outer conductor 26 and the center conductor 28. When the center conductor 28 and the outer conductor 26 are formed, the backing layer 42 resides on the second surface 18 or the substrate 14. This allows the deposited metallic or conductive material that ultimately forms the outer conductor 26 and center 28 to be retained within the cylindrical void 44 and the central bore 46, respectively. In one particular embodiment, the deposition of the metallic or conductive material that forms the outer conductor 26 and the center conductor 28 is a liquid metal material that cures and interfaces with the seedling layer 48 to extend entirely through the thickness 20 of the substrate 14.

FIG. 4D depicts the creation of assembly 10 in which the backing layer 42 is removed from the second surface 18 of the substrate 14 as indicated by arrows B. Subsequent to the removal of backing layer 42, the assembly 10 is formed and the central through-via 12 extends entirely through the thickness 20 of substrate 14 in which the material forming the substrate 14 that is external to the outer diameter 30 of the outer conductor 26 is the same as the inner material 34 (i.e., the annular member) that is within the inner diameter 32 of the outer conductor 26 and exterior to the outer diameter of the surface defining the cylindrical perimeter of the center conductor 28. The second surface 18 does not need to be polished, etched, grinded or otherwise altered upon the removal of the backing layer 42, thus, minimizing the manufacturing needs after creation of the via 12. In one particular embodiment, backing layer 42 can be applied via an adhesive, such as a pressure sensitive adhesive that is easily peeled away leaving little to no residue on the second surface 18 to further eliminate the need for any polishing, grinding or subsequent manipulations after the removal of backing 42. The thickness of backing layer 42 may be very thin relative to the thickness 20 of the substrate 14. In one particular embodiment, the thickness of the backing layer 42 or the wafer on the backing layer 42 may be approximately 30 microns.

The embodiment depicted in FIG. 4A-FIG. 4D may be beneficial because after the removal of the backing layer, which may be a wafer, there is no need for polishing the second surface of the substrate 14 to gain access to the conductor 26 and the conductor 28. This may be advantageous because polishing can be challenging because it introduces irregularities and roughness to the polished surface.

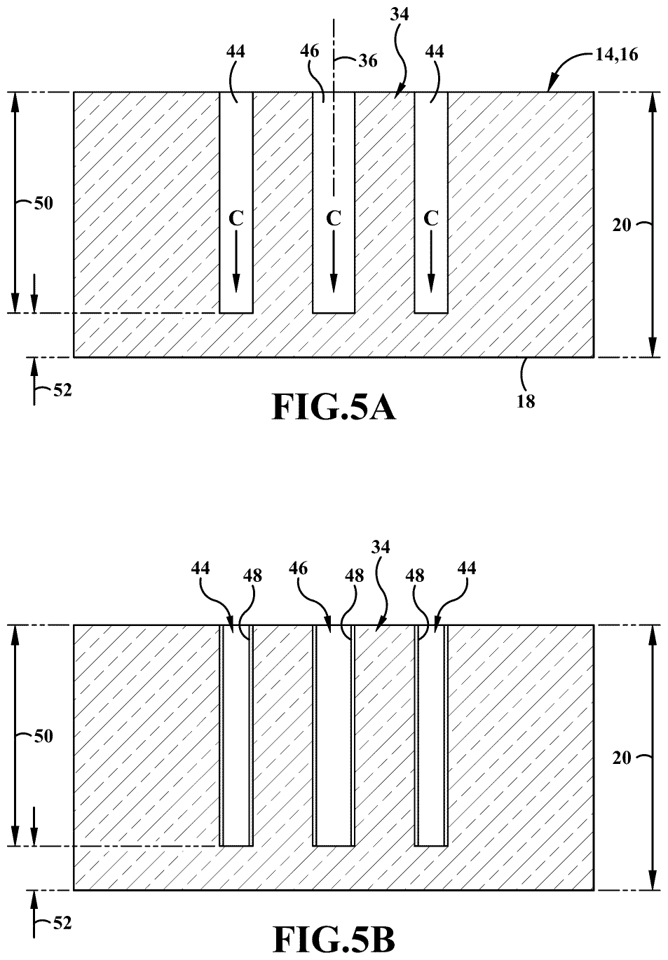

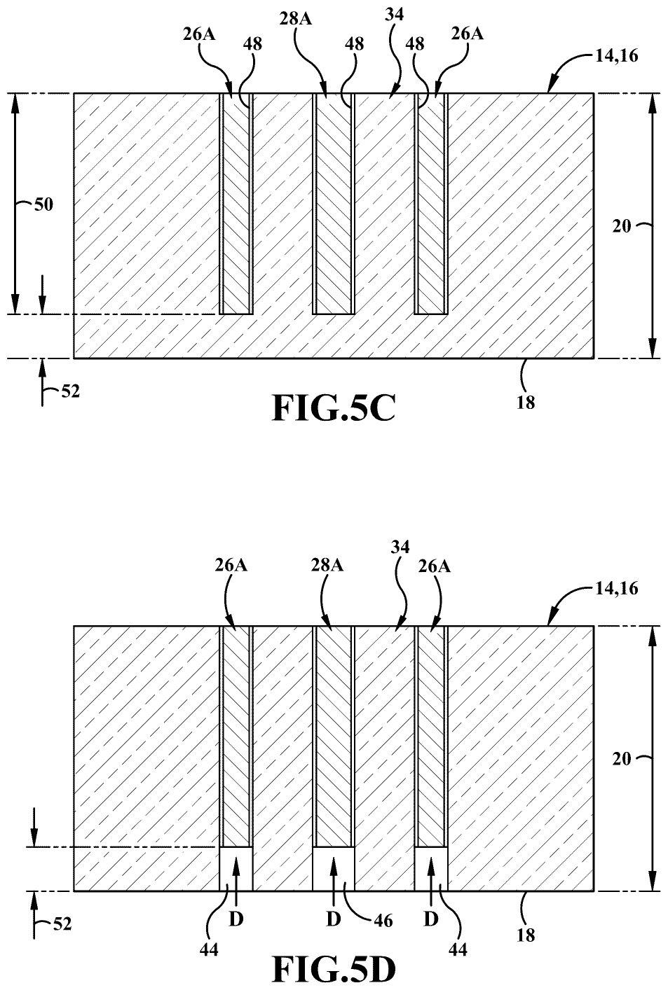

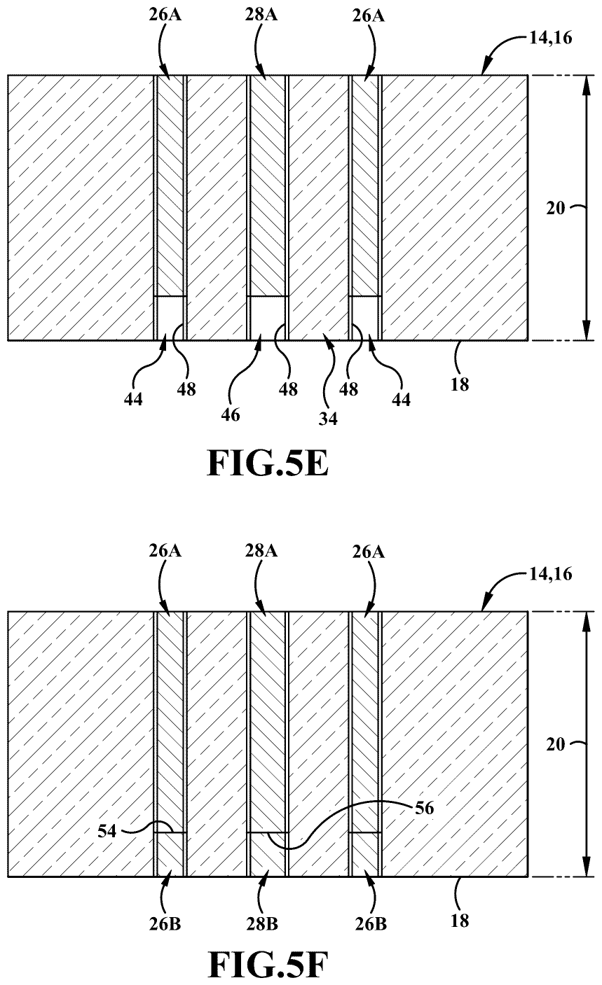

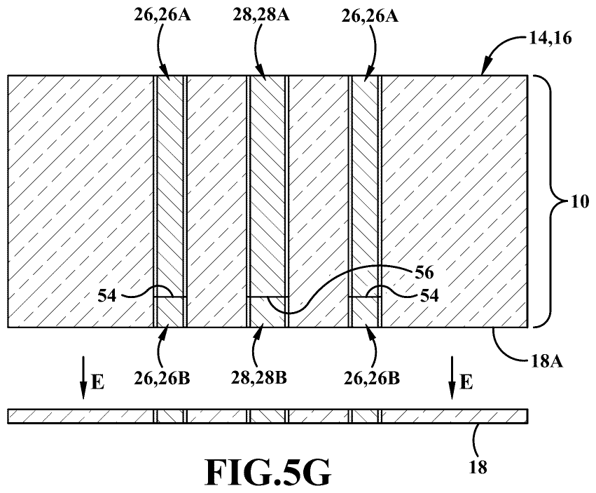

FIG. 5A-FIG. 5F depict another method of manufacture of assembly 10. FIG. 5A depicts that the cylindrical void 44 and the central bore 46 may be formed in the substrate 14 to a depth 50 that is less than the total thickness 20 of substrate 14. The reason that the depth 50 is less than the thickness 20 is to allow a remainder portion 52 of the substrate 14 to be utilized to retain the inner material 34 or annular member, which is the same as the outer material of substrate 14, to be used to hold the inner material 34 in place as the cylindrical void 44 and the central bore 46 are formed or created as indicated by arrows C (e.g., thereby eliminating the need for using a backing layer or release liner). The remainder portion 52 can be any amount that sums with the depth 50 to equal the total thickness 20 of the substrate 14. In one particular embodiment, the depth 50 is approximately 80% of the total thickness 20 of substrate 14. In another exemplary embodiment, the depth 50 greater than approximately 50% of the total thickness 20 of substrate 14 (i.e., the depth may be any dimension between about 50% and about 99.99% of the total thickness 20 of substrate 14. However, it is to be understood that any amount of depth 50 and remainder portion 52 is possible so long as the total sums to the dimension of thickness 20. When the cylindrical void 44 and the vertical central bore 46 have been formed as shown in FIG. 5A, they may then be coated with the seeding layer 48 as shown in FIG. 5B, in the manners previously described herein. When the seeding layer 48 is applied to the surfaces that define cylindrical void 44 and central bore 46, the remainder portion 52 maintains the inner material 34 or annular member in a stationary or fixed position. The manner in which the cylindrical void 44 and central bore 46 are formed in FIG. 5A may be accomplished through any known manner, however it is envisioned that the laser etching process previously described would be utilized.

FIG. 5C depicts that after the seeding layer 48 has been applied, the deposition of the metal or conductive materials could be inserted into the cylindrical void 44 and the central bore 46 to define a partial outer conductor 26A and a partial center conductor 28A. The partial outer conductor 26A and the partial center conductor 28A formed in the substrate to a depth equal to the depth 50.

Thereafter, FIG. 5D depicts the remainder of the process in forming assembly 10. After the deposition of partial outer conductor 26A and partial center conductor 28A, a laser etching process may occur from the second surface 18 as indicated by arrows D to complete the remainder of the bore and the void from the second surface 18. The depth of the bore up from the second surface is equal to the remainder portion 52. Because the second boring from the second surface 18 occurs after the partial conductors 26A, 28A have been formed, when the second boring or etching occurs, as indicated in FIG. 5D, the solidarity of the conductors 26A, 28A maintain the inner material 34 in its position and secured rigidly to the remainder of the substrate 14.

FIG. 5E depicts that the secondary void and bore may be coated with the seeding layer 48 so as to receive additional metallic material that is to be deposited in the secondary void and bore. FIG. 5F depicts the deposition of the metallic or conductive material into the secondary cylindrical void and the secondary bore. The deposition of the second outer conductor 26B and the second center conductor 28B solidifies and interfaces with the partial outer conductor 26A and center conductor 28A, respectively. The interface 54 of the partial outer conductor 26A and partial outer conductor 26B occurs at the plane where the depth 50 meets the remainder portion 52. Similarly, the interface 56 between the partial center conductor 28A and the partial center conductor 28B may lie along the same plane. However it is to be understood that the depth 50 can vary between the cylindrical void 44 and the central bore 46. For example, the depth at which the central bore 46 in laser etched or otherwise formed in the substrate 14 may occur deeper or shallower than that of the cylindrical void 44.

FIG. 5G represents that after the outer conductor 26 and the center conductor 28 have been formed through the partial process of forming partial conductors 26A, 26B and partial conductors 28A, 28B, then second surface 18 may be polished to remove any irregularities in the second surface. The removal of the second surface 18 is indicated by arrows E which results in a polished second surface 18A.

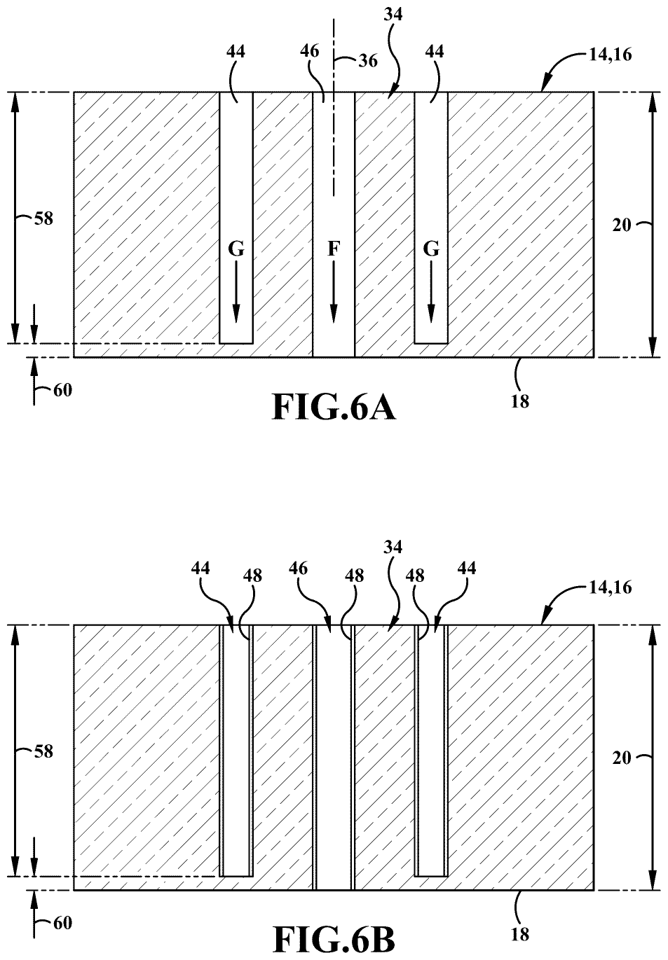

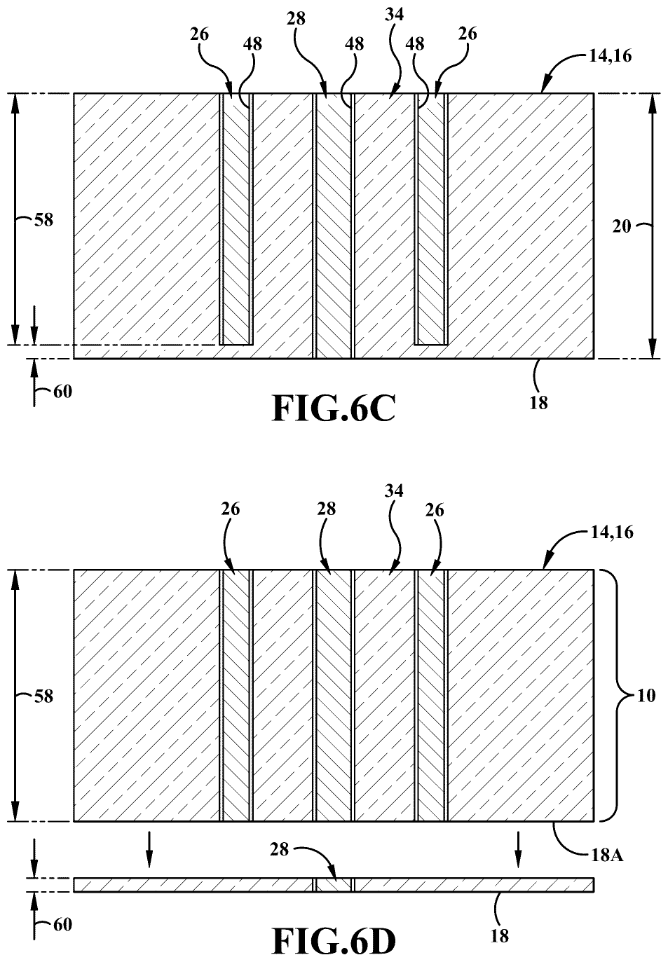

FIG. 6A depicts another method of operation to form assembly 10 in which the central bore 46 is formed entirely through the thickness 20 of substrate 14 as indicated by arrow F. However, the cylindrical void 44 is only partially formed through the thickness 20 of substrate 14 as indicated by arrows G. The partial formation of the cylindrical void 44 at a depth 58 that is less than the total thickness 20 of the substrate 14 leave a remainder portion 60 that is connected with the inner material 34 or annular member to retain the inner material in a stationary or fixed position. The creation or formation of the central bore 46 and the partial cylindrical void 44 may be accomplished through the laser etching process detailed herein, or alternatively, other processes may be utilized to create the central bore 46 and the partial cylindrical void 44. FIG. 6B depicts that seeding layer 48 may then be coated to the surface that defines the central bore 46 and the partial cylindrical void 44.

FIG. 6C depicts that the metal or conductive material may be inserted into the partial cylindrical void 44 and the central bore 46 to therein solidify and create the conductive material for the via 12. FIG. 6D depicts that the remainder portion 60 may then be removed via polishing or grinding to exposed a polished second surface 18A that thereby exposes the formed outer conductor 26 to be used as part of via 12.

Regardless of which formation technique is used to create assembly 10, the assembly 10 of the present disclosure assist with isolating signals that are transmitted through substrate 14. Although a single via 12 has been shown in and throughout the Figures, it is to be understood that the via 12 could be one via from a plurality of vias in a single substrate. The interconnection of integrated circuits (ICs) may require multiple isolated signal routing paths. The arrangement of vias, of which via 12 may be one of the vias in the pattern, may assist with RF shielding. In one exemplary embodiment, the castellation equidistant circular array of vias is what this disclosure is replacing with a single solid outer conductor. An array of via 12 is envisioned for MSIC die or RF MMICs that require multiple I/Os. A differential pair is also possible with two inner conductors 28 and one outer conductor 26.

Various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

All definitions, as defined and used herein, should be understood to control over dictionary definitions, definitions in documents incorporated by reference, and/or ordinary meanings of the defined terms.

The articles “a” and “an,” as used herein in the specification and in the claims, unless clearly indicated to the contrary, should be understood to mean “at least one.” The phrase “and/or,” as used herein in the specification and in the claims (if at all), should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc. As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

While components of the present disclosure are described herein in relation to each other, it is possible for one of the components disclosed herein to include inventive subject matter, if claimed alone or used alone. In keeping with the above example, if the disclosed embodiments teach the features of components A and B, then there may be inventive subject matter in the combination of A and B, A alone, or B alone, unless otherwise stated herein.

As used herein in the specification and in the claims, the term “effecting” or a phrase or claim element beginning with the term “effecting” should be understood to mean to cause something to happen or to bring something about. For example, effecting an event to occur may be caused by actions of a first party even though a second party actually performed the event or had the event occur to the second party. Stated otherwise, effecting refers to one party giving another party the tools, objects, or resources to cause an event to occur. Thus, in this example a claim element of “effecting an event to occur” would mean that a first party is giving a second party the tools or resources needed for the second party to perform the event, however the affirmative single action is the responsibility of the first party to provide the tools or resources to cause said event to occur.

When a feature or element is herein referred to as being “on” another feature or element, it can be directly on the other feature or element or intervening features and/or elements may also be present. In contrast, when a feature or element is referred to as being “directly on” another feature or element, there are no intervening features or elements present. It will also be understood that, when a feature or element is referred to as being “connected”, “attached” or “coupled” to another feature or element, it can be directly connected, attached or coupled to the other feature or element or intervening features or elements may be present. In contrast, when a feature or element is referred to as being “directly connected”, “directly attached” or “directly coupled” to another feature or element, there are no intervening features or elements present. Although described or shown with respect to one embodiment, the features and elements so described or shown can apply to other embodiments. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper”, “above”, “behind”, “in front of”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is inverted, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly. Similarly, the terms “upwardly”, “downwardly”, “vertical”, “horizontal”, “lateral”, “transverse”, “longitudinal”, and the like are used herein for the purpose of explanation only unless specifically indicated otherwise.

Although the terms “first” and “second” may be used herein to describe various features/elements, these features/elements should not be limited by these terms, unless the context indicates otherwise. These terms may be used to distinguish one feature/element from another feature/element. Thus, a first feature/element discussed herein could be termed a second feature/element, and similarly, a second feature/element discussed herein could be termed a first feature/element without departing from the teachings of the present invention.

An embodiment is an implementation or example of the present disclosure. Reference in the specification to “an embodiment,” “one embodiment,” “some embodiments,” “one particular embodiment,” “an exemplary embodiment,” or “other embodiments,” or the like, means that a particular feature, structure, or characteristic described in connection with the embodiments is included in at least some embodiments, but not necessarily all embodiments, of the invention. The various appearances “an embodiment,” “one embodiment,” “some embodiments,” “one particular embodiment,” “an exemplary embodiment,” or “other embodiments,” or the like, are not necessarily all referring to the same embodiments.

If this specification states a component, feature, structure, or characteristic “may”, “might”, or “could” be included, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

As used herein in the specification and claims, including as used in the examples and unless otherwise expressly specified, all numbers may be read as if prefaced by the word “about” or “approximately,” even if the term does not expressly appear. The phrase “about” or “approximately” may be used when describing magnitude and/or position to indicate that the value and/or position described is within a reasonable expected range of values and/or positions. For example, a numeric value may have a value that is +/−0.1% of the stated value (or range of values), +/−1% of the stated value (or range of values), +/−2% of the stated value (or range of values), +/−5% of the stated value (or range of values), +/−10% of the stated value (or range of values), etc. Any numerical range recited herein is intended to include all sub-ranges subsumed therein.

Additionally, the method of performing the present disclosure may occur in a sequence different than those described herein. Accordingly, no sequence of the method should be read as a limitation unless explicitly stated. It is recognizable that performing some of the steps of the method in a different order could achieve a similar result.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures.

To the extent that the present disclosure has utilized the term “invention” in various titles or sections of this specification, this term was included as required by the formatting requirements of word document submissions pursuant the guidelines/requirements of the United States Patent and Trademark Office and shall not, in any manner, be considered a disavowal of any subject matter.

In the foregoing description, certain terms have been used for brevity, clearness, and understanding. No unnecessary limitations are to be implied therefrom beyond the requirement of the prior art because such terms are used for descriptive purposes and are intended to be broadly construed.

Moreover, the description and illustration of various embodiments of the disclosure are examples and the disclosure is not limited to the exact details shown or described.

What is claimed is:

1. A signal transmission assembly product having a coaxial through-via configuration, wherein the coaxial through-via via entirely through a substrate from a first surface to a second surface, wherein the coaxial through-via via comprises an annular outer conductor, a cylindrical inner conductor that is centered along a center axis, and an annular inner member located between the outer conductor and the cylindrical inner conductor, wherein the annular inner member is formed form the same dielectric material as the substrate, the coaxial through-via configuration formed by a process comprising:
starting at the first surface, creating a cylindrical void that extends from the first surface toward the second surface;
starting at the first surface, creating a central bore that extends from the first surface toward the second surface;
maintaining the annular inner member in a fixed position between the cylindrical void and the central bore, wherein the annular inner member is formed from the same material as the substrate;
disposing a conductive material within the cylindrical void to create the annular outer conductor;
disposing a conductive material within the central bore to create the cylindrical inner conductor; and
forming a coaxial through-via that extends through the substrate.

2. The signal transmission assembly product formed by the process of claim 1, the process further comprising:
prior to creating the cylindrical void, applying a backing layer to the second surface of the substrate.

3. The signal transmission assembly product formed by the process of claim 2, the process further comprising:
after disposing the conductive material within the cylindrical void and disposing the conductive material within the central bore, removing the backing layer to expose the second surface.

4. The signal transmission assembly product formed by the process of claim 3, wherein maintaining the annular inner member in the fixed position between the cylindrical void and the central bore is accomplished by the backing layer being removably connected to both the substrate and the annular inner member.

5. The signal transmission assembly product formed by the process of claim 1, the process further comprising:
starting at the first surface, creating the cylindrical void that extends entirely through the substrate from the first surface to the second surface.

6. The signal transmission assembly product formed by the process of claim 1, the process further comprising:
starting at the first surface, creating the central bore that extends entirely through the substrate from the first surface to the second surface.

7. The signal transmission assembly product formed by the process of claim 1, the process further comprising:
starting at the first surface, creating a first portion of the cylindrical void that extends partially to a depth in the substrate from the first surface that is less than an entire thickness of the substrate, wherein a remainder portion of the substrate remains subsequent to creating the first portion of the cylindrical void and the remainder portion of the substrate maintains the annular inner member in a fixed position between the cylindrical void and the central bore.

8. The signal transmission assembly product formed by the process of claim 7, the process further comprising:
depositing the conductive material in the first portion of the cylindrical void;
starting from the second surface, creating a second portion of the cylindrical void that extends from the second surface through the remainder portion to meet with the conductive material in the first portion of the cylindrical void.

9. The signal transmission assembly product formed by the process of claim 1, the process further comprising:
starting at the first surface, creating a first portion of the central bore that extends partially to a depth in the substrate from the first surface that is less than an entire thickness of the substrate, wherein a remainder portion of the substrate remains subsequent to creating the first portion of the central bore and the remainder portion of the substrate maintains the annular member in a fixed position between the cylindrical void and the central bore.

10. The signal transmission assembly product formed by the process of claim 9, the process further comprising:
depositing the conductive material in the first portion of the central bore;
starting from the second surface, creating a second portion of the central bore that extends from the second surface through the remainder portion to meet with the conductive material in the first portion of the central bore.

11. A method comprising:
starting at a first surface on a substrate, creating a cylindrical void that extends from the first surface toward a second surface;
starting at the first surface, creating a central bore that extends from the first surface toward the second surface;
maintaining an annular member in a fixed position between the cylindrical void and the central bore, wherein the annular member is formed from the same material as the substrate;
disposing a conductive material within the cylindrical void;
disposing a conductive material within the central bore; and
forming a coaxial through-via that extends through the substrate.

12. The method of claim 11, further comprising:
prior to creating the cylindrical void, applying a backing layer to the second surface of the substrate.

13. The method of claim 12, further comprising:
after disposing the conductive material within the cylindrical void and disposing the conductive material within the central bore, removing the backing layer to expose the second surface.

14. The method of claim 13, wherein the annular member is maintained in the fixed position between the cylindrical void and the central bore by the backing layer prior to the backing layer being removed.

15. The method of claim 11, further comprising:
starting at the first surface, creating the cylindrical void that extends entirely through the substrate from the first surface to the second surface.

16. The method of claim 11, further comprising:
starting at the first surface, creating the central bore that extends entirely through the substrate from the first surface to the second surface.

17. The method of claim 11, further comprising:
starting at the first surface, creating a first portion of the cylindrical void that extends partially to a depth in the substrate from the first surface that is less than an entire thickness of the substrate, wherein a remainder portion of the substrate remains subsequent to creating the first portion of the cylindrical void and the remainder portion of the substrate maintains the annular member in a fixed position between the cylindrical void and the central bore.

18. The method of claim 17, further comprising:
depositing the conductive material in the first portion of the cylindrical void; and
starting from the second surface, creating a second portion of the cylindrical void that extends from the second surface through the remainder portion to meet with the conductive material in the first portion of the cylindrical void.

19. The method of claim 11, further comprising:
starting at the first surface, creating a first portion of the central bore that extends partially to a depth in the substrate from the first surface that is less than an entire thickness of the substrate, wherein a remainder portion of the substrate remains subsequent to creating the first portion of the central bore and the remainder portion of the substrate maintains the annular member in a fixed position between the cylindrical void and the central bore;
depositing the conductive material in the first portion of the central bore; and
starting from the second surface, creating a second portion of the central bore that extends from the second surface through the remainder portion to meet with the conductive material in the first portion of the central bore.

20. A signal transmission assembly comprising:
a substrate having a first surface and a second surface, wherein the substrate is formed from a dielectric material;
a via extending entirely through the substrate from the first surface to the second surface, wherein the via comprises:
an annular outer conductor;
a cylindrical inner conductor that is centered along a center axis; and
an annular member located between the outer conductor and the inner conductor, wherein the annular member is formed form the same dielectric material as the substrate.
